(19) United States
(12) Patent Application Publication
(10) Pub. No.: US 2003/0173108 A1
(43) Pub. Date: Sep. 18, 2003

(54) Semiconductor device and method of manufacturing the same, circuit board and electronic equipment

(75) Inventor: Michiyoshi Takano, Chino-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/331,114

(22) Filed: Dec. 27, 2002

(30) Foreign Application Priority Data
Jan. 18, 2002 (JP) 2002-009628

(51) Int. Cl. H01L 23/48; H05K 1/09

(52) U.S. Cl. 174/257; 174/260; 257/778

(57) ABSTRACT

A semiconductor device includes a semiconductor chip on which bumps are formed; and a substrate on which the semiconductor chip is mounted, the substrate including an interconnecting line to which each of the bumps is bonded. Surfaces of the bumps and a surface of the interconnecting line are formed of the same metal, and the interconnecting line is formed of a metal softer than nickel.

Japanese Patent Application No. 2002-9628 filed on Jan. 18, 2002, is hereby incorporated by reference in its entirety.

### BACKGROUND OF THE INVENTION

The present invention relates to a semiconductor device and a method of manufacturing the same, a circuit board, and electronic equipment.

Conventionally, a form in which a semiconductor chip is mounted on a substrate is known in the art. The substrate includes a base substrate and a plurality of interconnecting lines which are formed on the base substrate by etching, plating, or the like. The interconnecting lines are generally formed to have a structure including a copper layer which becomes a core, a gold layer formed on the surface, and a nickel layer for preventing diffusion of copper in gold which is formed between the copper layer and the gold layer. Bumps are generally formed by a gold layer. The bumps and the interconnecting lines are joined by thermocompression bonding.

Nickel is harder than gold and copper. Therefore, in the case where a nickel layer is used for the interconnecting lines, the interconnecting lines may become harder than the bumps. This may cause the bumps to be excessively deformed due to pressure applied by the interconnecting lines during thermocompression bonding, whereby the bumps may be spread in the widthwise direction and short-circuited with the adjacent bumps. Moreover, bonding strength between the bumps and the interconnecting lines may be decreased because the bumps are excessively deformed in comparison with the interconnecting lines and the like. These problems may occur not only in the case where the interconnecting lines include a metal material as hard as or harder than nickel, but also depending on the selection of the materials for the interconnecting lines and the bumps.

### BRIEF SUMMARY OF THE INVENTION

A semiconductor device according to one aspect of the present invention comprises:

a semiconductor chip on which bumps are formed; and

a substrate on which the semiconductor chip is mounted, the substrate including an interconnecting line to which each of the bumps is bonded,

wherein surfaces of the bumps and a surface of the interconnecting line are formed of the same metal, and

wherein the interconnecting line is formed of a metal softer than nickel.

A semiconductor device according to another aspect of the present invention comprises:

a semiconductor chip on which bumps are formed; and

a substrate on which the semiconductor chip is mounted, the substrate including an interconnecting line to which each of the bumps is bonded,

wherein at least a portion of the interconnecting line bonded to each of the bumps includes a core layer and a surface layer, the core layer including a layer formed of copper, and the surface layer being formed on a surface of the copper layer, and

wherein at least a portion of each of the bumps bonded to the interconnecting line and the surface layer are formed of gold.

A semiconductor device according to a further aspect of the present invention comprises:

a substrate which includes a base substrate, an interconnecting line and an insulating film, the substrate being formed on the base substrate, and the insulating film being provided on the interconnecting line and having an opening; and

a semiconductor chip on which bumps are formed, the semiconductor chip being provided on the substrate, and each of the bumps being bonded to the interconnecting line,

wherein the interconnecting line has a first section covered with the insulating film, and a second section located in the opening,

wherein the first section includes a core layer,

wherein the second section includes at least the core layer and a surface layer provided on a surface of the core layer,

wherein at least a portion of each of the bumps bonded to the interconnecting line is formed of the same metal as the surface layer, and

wherein the core layer and the surface layer are formed of a metal softer than nickel.

A circuit board according to a still further aspect of the present invention is electrically connected with the above semiconductor device.

Electronic equipment according to a yet further aspect of the present invention comprises the above semiconductor device.

A method of manufacturing a semiconductor device according to an even further aspect of the present invention comprises:

mounting a semiconductor chip on a substrate having an interconnecting line, the semiconductor chip having bumps formed thereon,

wherein surfaces of the bumps and a surface of the interconnecting line are formed of the same metal, and

wherein the interconnecting line is formed of a metal softer than nickel.

### BRIEF DESCRIPTION OF THE SEVERAL VIEWS OF THE DRAWING

FIG. 1 shows a semiconductor device according to an embodiment to which the present invention is applied;

FIG. 2 shows a semiconductor device according to the embodiment to which the present invention is applied;

FIG. 3 shows a semiconductor device according to the embodiment to which the present invention is applied;

FIG. 4 shows a circuit board according to an embodiment to which the present invention is applied;

FIG. 5 shows electronic equipment according to an embodiment to which the present invention is applied; and

FIG. 6 shows other electronic equipment according to an embodiment to which the present invention is applied.

### DETAILED DESCRIPTION OF THE EMBODIMENT

An embodiments of the present invention may provide a semiconductor device capable of preventing bumps from excessively deformed in the widthwise direction and capable of improving bonding strength between an interconnecting line and bumps and a method of manufacturing the same, a circuit board, and electronic equipment.

(1) A semiconductor device according to an embodiment of the present invention comprises:

a semiconductor chip on which bumps are formed; and

a substrate on which the semiconductor chip is mounted, the substrate including an interconnecting line to which each of the bumps is bonded,

wherein surfaces of the bumps and a surface of the interconnecting line are formed of the same metal, and

wherein the interconnecting line is formed of a metal softer than nickel.

According to the embodiment of the present invention, since the interconnecting line is formed of a metal softer than nickel, the interconnecting line can be prevented from being significantly harder than the bumps, whereby the bumps can be prevented from being excessively crushed. Therefore, occurrence of short circuits between the bumps can be prevented even in the case of a semiconductor chip at a narrow pitch. Moreover, since the bumps can be prevented from being excessively deformed in comparison with the interconnecting line, bonding strength between the bumps and the interconnecting line can be improved. In the embodiment of the present invention, the metal includes a metal, an alloy, and a metal compound.

(2) In this semiconductor device, the surfaces of the bumps and the surface of the interconnecting line may be formed of gold.

This enables each of the bumps and the interconnecting line to be joined by thermocompression bonding of gold.

(3) In this semiconductor device, the interconnecting line may include a core layer formed of a metal differing from a metal forming the surface of the interconnecting line.

(4) In this semiconductor device, the core layer of the interconnecting line may be formed of copper.

(5) A semiconductor device according to another embodiment of the present invention comprises:

a semiconductor chip on which bumps are formed; and

a substrate on which the semiconductor chip is mounted, the substrate including an interconnecting line to which each of the bumps is bonded,

wherein at least a portion of the interconnecting line bonded to each of the bumps includes a core layer and a surface layer, the core layer including a layer formed of copper, and the surface layer being formed on a surface of the copper layer, and

wherein at least a portion of each of the bumps bonded to the interconnecting line and the surface layer are formed of gold.

According to the embodiment of the present invention, bonding strength between the bumps and the interconnecting line can be improved by preventing the bumps from being excessively deformed in comparison with the interconnecting line.

(6) A semiconductor device according to a further embodiment of the present invention comprises:

a substrate which includes a base substrate, an interconnecting line and an insulating film, the substrate being formed on the base substrate, and the insulating film being provided on the interconnecting line and having an opening; and

a semiconductor chip on which bumps are formed, the semiconductor chip being provided on the substrate, and each of the bumps being bonded to the interconnecting line,

wherein the interconnecting line has a first section covered with the insulating film, and a second section located in the opening,

wherein the first section includes a core layer,

wherein the second section includes at least the core layer and a surface layer provided on a surface of the core layer,

wherein at least a portion of each of the bumps bonded to the interconnecting line is formed of the same metal as the surface layer, and

wherein the core layer and the surface layer are formed of a metal softer than nickel.

According to the embodiment of the present invention, since the bumps can be prevented from being excessively deformed in comparison with the interconnecting line, bonding strength between the bumps and the interconnecting line can be improved. In the embodiment of the present invention, the metal includes a metal, an alloy, and a metal compound.

(7) In this semiconductor device, at least a portion of the core layer in contact with the surface layer may be formed of copper, and the surface layer may be formed of gold.

(8) A circuit board according to a still further embodiment of the present invention is electrically connected with the above semiconductor device. (9) Electronic equipment according to a yet further embodiment of the present invention comprises the above semiconductor device. (10) A method of manufacturing a semiconductor device according to an even further embodiment of the present invention comprises:

mounting a semiconductor chip on a substrate having an interconnecting line, the semiconductor chip having bumps formed thereon,

wherein surfaces of the bumps and a surface of the interconnecting line are formed of the same metal, and

wherein the interconnecting line is formed of a metal softer than nickel.

According to an embodiment of the present invention, since the interconnecting line is formed of a metal softer than nickel, the interconnecting line can be prevented from being significantly harder than the bumps, whereby the bumps can be prevented from being excessively deformed. Therefore, occurrence of short circuits between the bumps can be prevented even in the case of a semiconductor chip at a narrow pitch. Moreover, since the bumps can be prevented from being excessively deformed in comparison with the interconnecting line, bonding strength between the bumps and the interconnecting lines can be improved. In the embodiment of the present invention, the metal includes a metal, an alloy, and a metal compound.

Embodiments of the present invention are described below with reference to the drawings. However, the present invention is not limited to these embodiments.

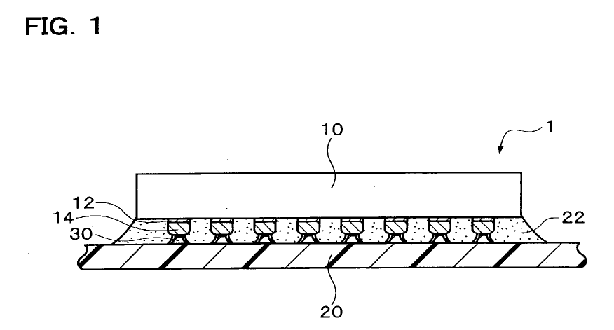

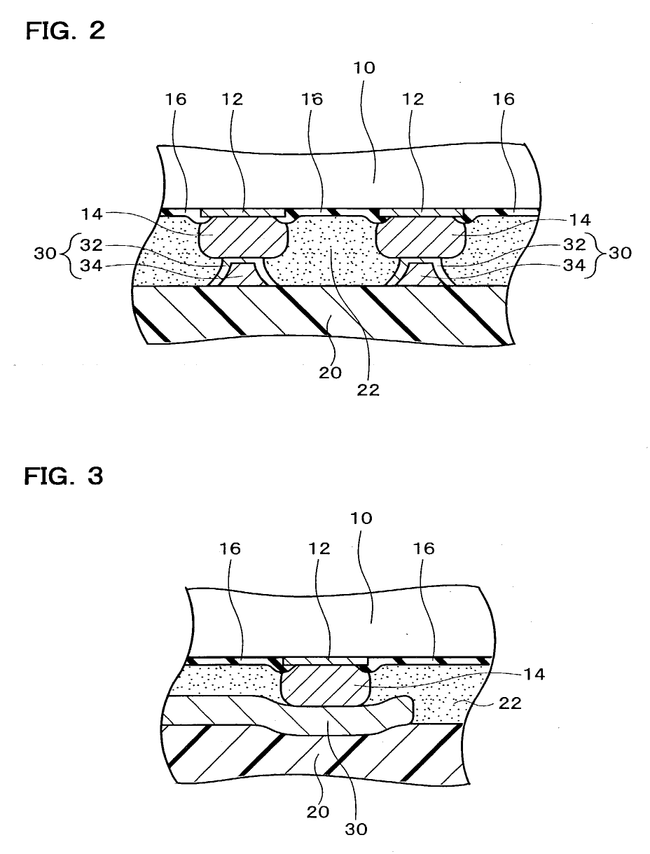

FIGS. 1 to 3 show a semiconductor device according to the present embodiment. FIG. 2 is a cross-sectional view in a direction which intersects the axial direction of interconnecting line of a substrate at right angles. FIG. 3 is a cross-sectional view along the axial direction of the interconnecting line of the substrate. A semiconductor device according to the present embodiment includes a semiconductor chip 10 and a substrate 20.

The semiconductor chip 10 may be formed in the shape of a sphere. Generally, the semiconductor chip 10 is formed in the shape of a rectangular parallelepiped. The semiconductor chip 10 has a plurality of pads 12. The pads 12 are generally formed on the surface of the semiconductor chip 10 on which an integrated circuit is formed. The pads 12 may be formed of a metal including aluminum or copper. The pads 12 are generally formed at the edge of the semiconductor chip 10. The pads 12 may be formed on opposite two sides or four sides of the semiconductor chip 10, for example.

As shown in FIGS. 2 and 3, a passivation film 16 may be formed on the semiconductor chip 10 in a manner to avoid the pads 12. The passivation film 16 may be formed of SiO₂, SiN, a polyimide resin, or the like. The passivation film 16 preferably covers the edge of the pads 12.

Bumps 14 are formed on the pads 12 of the semiconductor chip 10. The bumps 14 are formed in the shape of a projection. The bumps 14 may be formed by using a ball bump method in which a bonding wire is melted and formed in the shape of a ball, for example. The bumps 14 may be formed by electroplating or electroless plating. In this case, the shape of a projection of the bumps 14 may be a straight wall type which is formed by using a mask, or a mushroom type which is formed without using a mask.

The bumps 14 may be formed of a single layer as shown in the figures. The bumps 14 may also be formed of a plurality of layers. In the case of a plurality of layers, the bump 14 has an inner layer (core layer) and an outer layer (surface layer) provided at least on the surface of the inner layer (core layer). The outer layer (surface layer) of the bump 14 may cover the entire inner layer (core layer), or cover only the upper surface of the inner layer.

The surface of the bumps 14 may be formed of gold. Gold used as the material for the bumps 14 may contain a small amount of copper. In the case where the bumps 14 are formed of a single layer as shown in the figures, the bumps 14 may be gold bumps. In this case, the gold bumps may be formed on the pads 12 by using the ball bump method. In the case where the bumps 14 are formed of a plurality of layers, the surface layer may be formed of gold. In this case, the core layer of the bumps 14 may be formed of copper. In the case where the core layer of the bumps 14 includes a layer formed of copper, the surface layer may be formed on the surface of the copper layer. A nickel layer may be interposed between the surface layer and the core layer for preventing diffusion of copper and gold. Such bumps may be formed by electroplating or electroless plating, for example.

The substrate 20 includes interconnecting lines 30 and a base substrate which supports the interconnecting lines 30. The material for the base substrate may be either an organic material or an inorganic material. The material for the base substrate may be a composite structure of organic and inorganic materials. As the base substrate, a flexible substrate made of apolyimide resin, polyethyleneterephthalate (PET), or the like may be used. The flexible substrate may be a Chip On Film (COF) substrate or a Tape Automated Bonding (TAB) substrate. Specifically, the substrate 20 maybe a flexible film. A ceramic substrate, a glass substrate, or a glass epoxy substrate may be used as the base substrate, for example.

The interconnecting lines 30 are formed on one surface or two opposite surfaces of the base substrate. The interconnecting lines 30 used herein refer to portions for electrically connecting at least two points. A plurality of the interconnecting lines 30 which are independently formed may be referred to as an interconnecting pattern. The interconnecting lines 30 may be formed by etching conductive foil provided on the base substrate. The interconnecting lines 30 may be formed by electroplating or electroless plating.

A part of the interconnecting line 30 becomes a joint section with the bump 14. The entire interconnecting line 30 including the joint section may be linear in which almost the same cross section continues. The interconnecting line 30 may be formed thinner at the upper end than at the base section thereof on the side of the base substrate. In this case, the width of the upper end of the interconnecting line 30 may be smaller than the width of the bump 14. The joint section of the interconnecting line 30 may be a land having a width greater than the width of other section (line). The width of the land may be greater than the width of the bump 14.

The interconnecting lines 30 may be formed of a plurality of layers as shown in FIG. 2. In FIG. 2, the interconnecting line 30 includes a surface layer 32, and a core layer 34 which is formed of a metal material differing from the surface layer 32. The surface layer 32 may cover the entire surface of the core layer 34 as shown in FIG. 2, or cover only the upper surface of the core layer 34. The interconnecting lines 30 may be formed of a single layer differing from the example shown in FIG. 2. The surface layer 32 may be provided only in the area including the joint section between the interconnecting line 30 and the bump 14.

The surface of the interconnecting line 30 is formed of the same metal as the surface of the bump 14. The same metal used herein means that main components in the metal are (substantially) the same. It is unnecessary that the concentrations of impurities and the like be completely the same. The metal includes a metal, an alloy, and a metal compound. The surface of the interconnecting line 30 may be formed of gold in the same manner as the surface of the bump 14. Specifically, the surface layer 32 may be formed of gold. In this case, the core layer 34 may be formed of copper. Gold used as the material for the bump 14 may contain a small amount of copper. In the case where the core layer 34 includes a layer formed of copper, the surface layer 32 may be formed on the surface of the copper layer. The surface layer (gold layer) 32 may be formed as thick as about 1 μm or more. This prevents the metal (copper) of the core layer 34 diffused into the surface layer (gold layer) 32 from reaching the outermost surface of the interconnecting line 30. The surface layer (gold layer) 32 may be formed as thin as about 0.3 to 0.5 μm.

For example, the core layer (copper layer) 34 maybe formed by attaching copper foil to the base substrate through an adhesive and patterning the copper foil by isotropic etching. The surface layer (gold layer) 32 may be formed by immersing the core layer in a gold plating bath. The copper foil may be directly formed on the base substrate by sputtering or the like without using an adhesive. The surface layer (gold layer) 32 may be formed by depositing gold on the surface of the copper layer by electroplating.

For example, an insulating film (not shown) may be formed on the core layer 34 after forming the core layer 34 on the base substrate. Openings may be formed in the insulating film by removing the insulating film in the area which overlaps the area which becomes the joint section between the interconnecting lines 30 and the bumps 14. The surface layer (gold layer) 32 may be formed only on the upper surface or over the entire surface of the core layer 34 located in the openings. In this case, the substrate 20 includes the interconnecting lines 30 on the base substrate and the insulating film provided on the interconnecting lines 30, and the insulating film has openings. The interconnecting line 30 has a first section (not shown) covered with the insulating film, and a second section (not shown) located in the opening. In this case, the first section includes the core layer 34, and the second section includes the core layer 34 and the surface layer 32 formed at least on the surface of the core layer 34.

As shown in FIG. 1, the semiconductor chip 10 is mounted on the substrate 20. In more detail, the semiconductor chip 10 is mounted on the substrate 20 in a state in which the surface of the semiconductor chip 10 having the bumps 14 faces the substrate 20. Specifically, the semiconductor chip 10 is mounted face down on the substrate 20. The bumps 14 are bonded to the interconnecting lines 30. In the case where the surface layer of the bumps 14 and the surface layer of the interconnecting lines 30 are formed of gold, these surface layers are joined by thermocompression bonding. The gold may contain a small amount of copper.

In the present embodiment, the interconnecting lines 30 are formed of a metal softer than nickel. Specifically, the interconnecting lines 30 contain neither nickel nor a metal harder than nickel. The metal used herein includes a metal, an alloy, and a metal compound. The hard metal refers to a metal which is rarely plastically deformed. Copper and gold (including gold containing a small amount of copper) are softer than nickel.

If the interconnecting lines 30 do not contain a metal as hard as or harder than nickel, the interconnecting lines 30 can be made softer than in the case where the interconnecting lines 30 contain such a hard metal. Therefore, in the case of using a flexible substrate as the base substrate, the interconnecting line 30 is bent due to stress applied from the bump 14, as shown in FIG. 3. Specifically, since the interconnecting line 30 is bonded to the bump 14 so as to surround the bump 14, the bonding area between the interconnecting line 30 and the bump 14 is increased. This enables the bonding strength (peel strength) between the interconnecting line 30 and the bump 14 to be improved. For example, the peel strength between the interconnecting line 30 and the bump 14 can be made greater than the peel strength between the interconnecting line 30 and the base substrate.

Moreover, since the interconnecting line 30 can be prevented from being significantly harder than the bump 14, the bump can be prevented from being excessively deformed. In particular, in the case where the width of the upper end of the interconnecting line 30 is smaller than the width of the bump 14 as shown in FIG. 2, the bump 14 tends to be deformed and spread in the widthwise direction. In this case, it is effective to apply the present invention.

Since it is unnecessary to form nickel or the like by plating in the formation step of the interconnecting lines 30, the manufacturing cycle of the semiconductor device can be simplified.

As shown in FIGS. 1 to 3, a resin 22 may be provided between the semiconductor chip 10 and the substrate 20. The resin 22 may be an under-fill material. The electrical joint sections between the bumps 14 and the interconnecting lines 30 can be sealed by the resin 22. The resin 22 may be injected between the semiconductor chip 10 and the substrate 20 after mounting the semiconductor chip 10 on the substrate 20. The resin 22 may be provided in advance to either the semiconductor chip 10 or the substrate 20 before mounting the semiconductor chip 10.

According to the present embodiment, since the interconnecting lines 30 are formed of a metal softer than nickel, the interconnecting lines 30 can be prevented from being significantly harder than the bumps 14, whereby the bumps 14 can be prevented from being excessively deformed. Therefore, occurrence of short circuits between the bumps 14 can be prevented even in the case of the semiconductor chip 10 with a narrow pitch. Moreover, since the bumps 14 can be prevented from being excessively deformed in comparison with the interconnecting lines 30, the bonding strength between the bumps 14 and the interconnecting lines 30 can be improved.

The present invention is not limited to the above-described embodiment. In particular, any of the content described in the above embodiment may be selectively applied to the material for the interconnecting lines 30.

A method of manufacturing the semiconductor device according to the present embodiment includes mounting the semiconductor chip 10 on the substrate 20. The configurations of the bumps 14 and the interconnecting lines 30 are as described above. The description and the effects of the manufacturing method are also as described above.

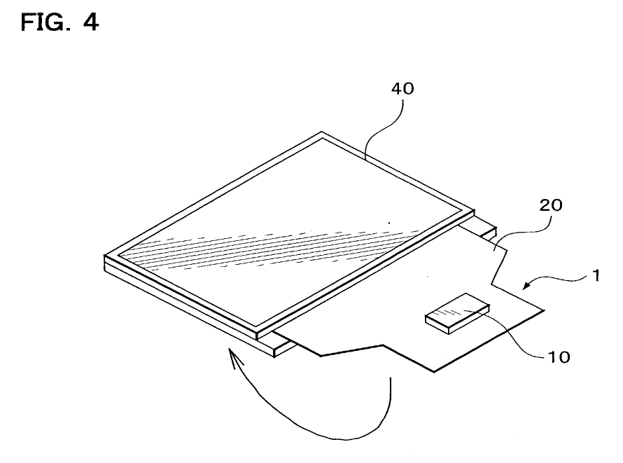

FIG. 4 shows a circuit board according to an embodiment to which the present invention is applied. As shown in FIG. 4, the above-described semiconductor device 1 is electrically connected with a circuit board 40. The circuit board 40 may be an electro-optical panel (liquid crystal panel, plasma display panel, electroluminescent display panel, or the like). As shown in FIG. 4, the substrate 20 of the semiconductor device 1 may be provided so as to be bent. For example, the substrate 20 may be bent around the edge of the circuit board 40.

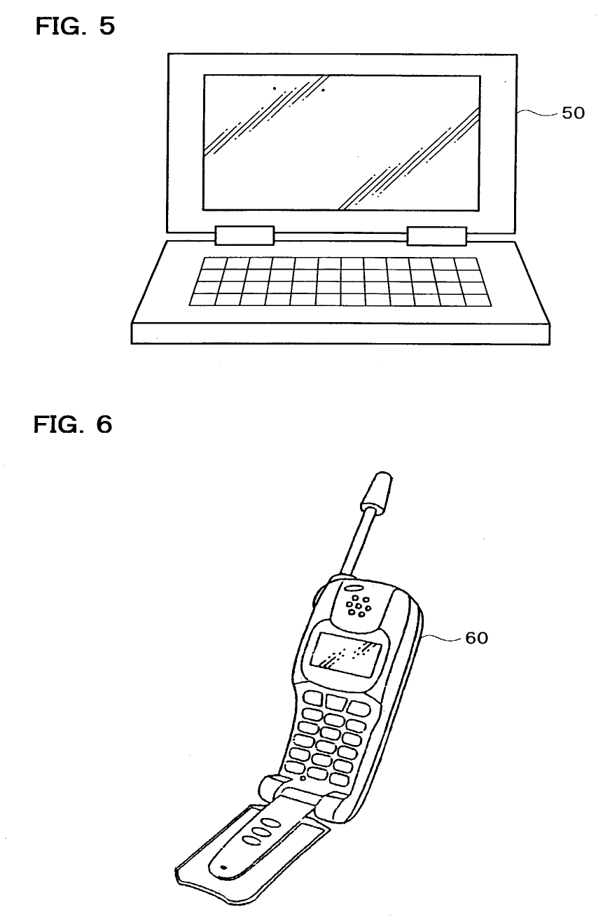

FIG. 5 shows a notebook-type personal computer 50 as an example of electronic equipment including a semiconductor device to which the present invention is applied. FIG. 6 shows a portable telephone 60. These pieces of electronic equipment also include the circuit board 40 (electro-optical panel, for example).

What is claimed is:

1. A semiconductor device comprising:
a semiconductor chip on which bumps are formed; and
a substrate on which the semiconductor chip is mounted, the substrate including an interconnecting line to which each of the bumps is bonded,
wherein surfaces of the bumps and a surface of the interconnecting line are formed of the same metal, and
wherein the interconnecting line is formed of a metal softer than nickel.

2. The semiconductor device as defined by claim 1, wherein the surfaces of the bumps and the surface of the interconnecting line are formed of gold.

3. The semiconductor device as defined by claim 1, wherein the interconnecting line includes a core layer formed of a metal differing from a metal forming the surface of the interconnecting line.

4. The semiconductor device as defined by claim 2, wherein the interconnecting line includes a core layer formed of a metal differing from a metal forming the surface of the interconnecting line.

5. The semiconductor device as defined by claim 3, wherein the core layer of the interconnecting line is formed of copper.

6. The semiconductor device as defined by claim 4, wherein the core layer of the interconnecting line is formed of copper.

7. A semiconductor device comprising:
a semiconductor chip on which bumps are formed; and
a substrate on which the semiconductor chip is mounted, the substrate including an interconnecting line to which each of the bumps is bonded,
wherein at least a portion of the interconnecting line bonded to each of the bumps includes a core layer and a surface layer, the core layer including a layer formed of copper, and the surface layer being formed on a surface of the copper layer, and
wherein at least a portion of each of the bumps bonded to the interconnecting line and the surface layer are formed of gold.

8. A semiconductor device comprising:
a substrate which includes a base substrate, an interconnecting line and an insulating film, the substrate being formed on the base substrate, and the insulating film being provided on the interconnecting line and having an opening; and
a semiconductor chip on which bumps are formed, the semiconductor chip being provided on the substrate, and each of the bumps being bonded to the interconnecting line,
wherein the interconnecting line has a first section covered with the insulating film, and a second section located in the opening,
wherein the first section includes a core layer,
wherein the second section includes at least the core layer and a surface layer provided on a surface of the core layer,
wherein at least a portion of each of the bumps bonded to the interconnecting line is formed of the same metal as the surface layer, and
wherein the core layer and the surface layer are formed of a metal softer than nickel.

9. The semiconductor device as defined by claim 8,
wherein at least a portion of the core layer in contact with the surface layer is formed of copper, and
wherein the surface layer is formed of gold.

10. A circuit board which is electrically connected with the semiconductor device as defined by claim 1.

11. A circuit board which is electrically connected with the semiconductor device as defined by claim 3.

12. A circuit board which is electrically connected with the semiconductor device as defined by claim 4.

13. A circuit board which is electrically connected with the semiconductor device as defined by claim 7.

14. A circuit board which is electrically connected with the semiconductor device as defined by claim 8.

15. Electronic equipment comprising the semiconductor device as defined by claim 1.

16. Electronic equipment comprising the semiconductor device as defined by claim 3.

17. Electronic equipment comprising the semiconductor device as defined by claim 4.

18. Electronic equipment comprising the semiconductor device as defined by claim 7.

19. Electronic equipment comprising the semiconductor device as defined by claim 8.

20. A method of manufacturing a semiconductor device comprising:
mounting a semiconductor chip on a substrate having an interconnecting line, the semiconductor chip having bumps formed thereon,
wherein surfaces of the bumps and a surface of the interconnecting line are formed of the same metal, and
wherein the interconnecting line is formed of a metal softer than nickel.
